(19) United States
(12) Patent Application Publication
(10) Pub. No.: US 2007/0085115 A1
(43) Pub. Date: Apr. 19, 2007

(54) MEMORY CELL, PIXEL STRUCTURE AND MANUFACTURING PROCESS OF MEMORY CELL FOR DISPLAY PANELS

(76) Inventors: Hung-Tse Chen, Hsinchu County (TW); Chi-Lin Chen, Hsinchu City (TW); Yu-Cheng Chen, Hsinchu City (TW); Chi-Wen Chen, Chiayi County (TW); Ting-Chang Chang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,612

(22) Filed: Apr. 12, 2006

(30) Foreign Application Priority Data
Oct. 13, 2005 (TW) 94135662

(51) Int. Cl. H01L 31/113; H01L 31/062; H01L 21/84; H01L 21/00

(52) U.S. Cl. 257/291; 438/151

(57) ABSTRACT

A memory cell, suitable for being disposed on a substrate, comprises a poly-Si island, a first dielectric layer, a trapping layer, a second dielectric layer and a control gate. The poly-Si island is disposed on the substrate and includes a source doped region, a drain doped region and a channel region there-between. The first dielectric layer is disposed on the poly-Si island, the trapping layer is disposed on the first dielectric layer, the second dielectric layer is disposed on the trapping layer and the control gate is disposed on the second dielectric layer. The above-described memory cell can be integrated into the manufacturing process of a low temperature polysilicon LCD panel (LTPS LCD panel) or an organic light emitting display panel (OLED panel).

### CROSS-REFERENCE TO RELATED APPLICATION

This application claims the priority benefit of Taiwan application serial no. 94135662, filed on Oct. 13, 2005. All disclosure of the Taiwan application is incorporated herein by reference.

### BACKGROUND OF THE INVENTION

1. Field of Invention

The present invention relates to a memory cell and a manufacturing process thereof, and particularly to a MONOS (metal-oxide-nitride-oxide-polysilicon) type memory cell suitable for being fabricated on a glass substrate.

2. Description of the Related Art

Due to the features of light-weight and compactness, the liquid crystal display (LCD) and the organic light emitting display (OLED) have gradually become display tools of the portable terminal systems in the last twenty years. In particular, the twist nematic liquid crystal display (TN-LCD), the super twist nematic liquid crystal display (STN-LCD), the thin film transistor liquid crystal display (TFT-LCD) and the organic light emitting display (OLED) have become indispensable daily used products for people. In a common TFT-LCD, a pixel thereof is mainly comprised of a TFT, a storage capacitor and a pixel electrode. The image data to be written into each pixel would be stored in the storage capacitor and be updated frame by frame. Therefore, the TFT-LCD with such architecture has a high power-consumption.

For many portable electronic products today, the LCD thereof displays static images for the most of the time. Thus, it is not necessary to refresh the image data stored in a pixel all the time. Under such situation, if a memory, such as a static random access memory (SRAM) or a dynamic random access memory (DRAM), can be buried in each pixel, the LCD power-consumption would be largely reduced.

FIG. 1 is a circuit diagram of a conventional pixel structure. Referring to FIG. 1, a conventional pixel structure 100 for displaying static frames includes a TFT 110, a liquid crystal capacitor 120, a memory control circuit 130 and a SRAM 140. Wherein, the gate G of the TFT 110 is electrically connected to a scan line DL, the source S of the TFT 110 is electrically connected to a data line DL and the drain D of the TFT 110 is electrically connected to a liquid crystal capacitor 120. In addition, the drain D of the TFT 110 is electrically connected to the SRAM 140 through the memory control circuit 130, so that the image signal input into the liquid crystal capacitor 120 from the data line DL can be stored in the SRAM 140 through the memory control circuit 130.

Under the condition of displaying static images, since the SRAM 140 can remain the voltage difference of the liquid crystal capacitor 120 without updating the data all the time, the power-consumption can be largely reduced. However, since a SRAM 140 is comprised of four TFTs T1 and a memory control circuit 130 is comprised of two TFTs T2, the circuit layout of the pixel structure 100 is considerably crowded. Moreover, because the TFTs T1 and T2 adversely affect the aperture ratio of the pixel structure 100, the pixel structure 100 is applicable to a reflective LCD panel, and not suitable for a transmissive LCD panel.

### SUMMARY OF THE INVENTION

Based on the above described, an object of the present invention is to provide a memory cell, suitable to be integrated in a low temperature polysilicon TFT (LTPS-TFT).

Another object of the present invention is to provide a pixel structure with low power-consumption.

A further object of the present invention is to provide a memory cell manufacturing process, suitable to be integrated with the LTPS-TFT manufacturing process.

To achieve the above-described objects or the others, the present invention provides a memory cell suitable for being disposed on a substrate. The memory cell includes a poly-island, a first dielectric layer, a trapping layer, a second dielectric layer and a control gate. Wherein, the poly-Si island includes a source doped region, a drain doped region and a channel region disposed between the source doped region and the drain doped region. The first dielectric layer is disposed on the poly-Si island, the trapping layer is disposed on the first dielectric layer, the second dielectric layer is disposed on the trapping layer and the control gate is disposed on the second dielectric layer.

To achieve the above-described objects or the others, the present invention provides a pixel structure suitable for electrically connecting a scan line and a data line. The pixel structure includes an active device, a pixel electrode, a control circuit and one or a plurality of the above-described memory cells (for example, a single memory cell or a memory cell array). Wherein, the pixel electrode is electrically connected to the scan line and the data line through the active device, and the memory cell is electrically connected with the control circuit and the pixel electrode. The above-described active device is, for example, a TFT. The control circuit is formed by, for example, a single TFT or a plurality of TFTs.

In an embodiment of the present invention, the source doped region and the drain doped region are N-type doped regions.

In an embodiment of the present invention, the material of the first dielectric layer can be silicon dioxide, the material of the trapping layer can be silicon nitride, while the material of the second dielectric layer can be silicon dioxide.

In an embodiment of the present invention, the control gate can reside over the channel region. In another embodiment of the present invention however, the control gate can disposed over the channel region, a portion of the source doped region and a portion of the drain doped region.

In an embodiment of the present invention, the poly-Si island can further include a charge-induced doped region residing between the channel region and the drain doped region and below the control gate. Besides, the width of the charge-induced doped region is, for example, smaller than or equal to the width of the channel region and the charge-induced doped region is, for example, a P-type doped region.

In an embodiment of the present invention, the memory cell can further include a buffer layer disposed between the substrate and the poly-Si island.

In an embodiment of the present invention, the memory cell can further include a source contact metal and a drain contact metal, wherein the source contact metal electrically connects with the source doped region, while the drain contact metal electrically connects with the drain doped region.

To achieve the above-described objects or the others, the present invention provides a memory cell manufacturing process and the manufacturing process includes the following steps. First, a poly-Si island is formed on a substrate, wherein the poly-Si island includes a source doped region, a drain doped region and a channel region between the source doped region and the drain doped region. Next, a first dielectric layer, a trapping layer and a second dielectric layer are sequentially formed on the poly-Si island. Afterwards, a control gate is formed on the second dielectric layer.

In an embodiment of the present invention, the method to form the poly-Si island includes the following steps. First, an amorphous silicon layer is formed on the substrate and subsequently, the film is dehydrogenated by furnace annealing. Next, the amorphous silicon layer is re-crystallized to become a polysilicon layer by using an annealing process. Afterwards, the polysilicon layer is patterned and doped to form a source doped region, a drain doped region, and a channel region. The above-mentioned annealing process is, for example, an excimer laser annealing process (ELA process), while the method for forming the source doped region and the drain doped region is, for example, conducting N-type doping to the polysilicon layer.

In an embodiment of the present invention, a charge-induced doped region can be further formed between the channel region and the drain doped region, wherein the charge-induced doped region is disposed below the control gate.

In an embodiment of the present invention, the method for forming the charge-induced doped region is, for example, conducting P-type doping to the polysilicon layer.

In an embodiment of the present invention, a buffer layer can be further formed between the substrate and the poly-Si island.

In an embodiment of the present invention, a source contact metal and a drain contact metal can be further formed, wherein the source contact metal electrically connects with the source doped region, while the drain contact metal electrically connects with the drain doped region.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a circuit diagram of a conventional pixel structure.

FIG. 2 is a circuit diagram of a pixel structure of the present invention.

FIG. 3A and FIG. 3B are diagrams of a memory cell in the first embodiment of the present invention.

FIGS. 4A˜4E are diagrams showing the steps of the manufacturing process of the memory cell in FIG. 3A.

FIG. 5A and FIG. 5B are diagrams of a memory cell in the second embodiment of the present invention.

FIGS. 6A˜6E are diagrams showing the steps of the manufacturing process of the memory cell in FIG. 5A.

FIGS. 7A, 7B and 7C are diagrams of a memory cell in the third embodiment of the present invention.

FIGS. 8A˜8E are diagrams showing the steps of the manufacturing process of the memory cell in FIG. 7A.

FIG. 9 is a graphic chart of source current ID VS. control gate voltage VG of the memory cells of the present invention.

FIG. 10 is a diagram of energy-bands corresponding to programming and erasing the memory cells of the present invention, respectively.

FIG. 11 is a graphic chart of threshold voltage vs. programming/erasing time of the memory cells of the present invention.

FIG. 12 is a graphic chart of threshold voltage vs. programming/erasing times of the memory cells of the present invention.

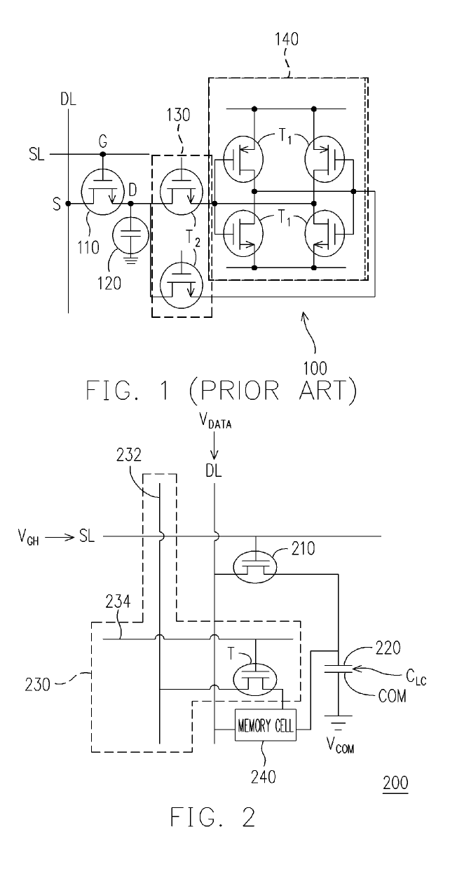

### DESCRIPTION OF THE EMBODIMENTS

FIG. 2 is a circuit diagram of a pixel structure of the present invention. Referring to FIG. 2, a pixel structure 200 of the present invention is suitable for electrically connecting a scan line SL and a data line DL. The pixel structure 200 includes an active device 210, a pixel electrode 220, a control circuit 230 and a memory cell 240. The pixel electrode 220 is electrically connected to the scan line SL and the data line DL through the active device 210 and the memory cell 240 electrically connects with the control circuit 230 and the pixel electrode 220. In the present invention, the active device 210 is, for example, a TFT, the control circuit 230 is, for example, a single TFT or a plurality of TFTs, while the memory cell 240 is a single memory cell or a memory cell array of any type.

It can be seen from FIG. 2 that the pixel electrode 220 electrically connected to the active device 210 is usually disposed under the subtend substrate (for example, a color filter) and a liquid crystal layer is filled between the pixel electrode 220 and a common electrode COM, so that a liquid crystal capacity C_{LC} is formed between the pixel electrode 220, the common electrode COM coupled to a voltage V_{COM} and the liquid crystal layer.

Referring to FIG. 2, besides the TFT T, the control circuit 230 further includes a control line 232 and a control line 234. The control line 232 is electrically connected to the gate of the TFT T, the control line 234 is electrically connected to the drain of the TFT T, and the source of the TFT T is electrically connected to the memory cell 240.

From FIG. 2, when a high voltage V_{GH} is applied to the scan line SL, the active device 210 takes a threshold state and the image data V_{DATA} is written into the pixel electrode 220 via the data line and the active device 210. Meanwhile, the memory cell 240 is ready to be written through the controls of the control line 323, the control line 324 and the TFT T, and the image data V_{DATA} can be stored in the memory cell 240 via the data line. On the other hand, when the pixel structure 200 is used for displaying static images, the voltage level of the pixel electrode 220 thereof can be remained by the image data V_{DATA} stored in the memory cell 240. In other words, through the controls of the control line 323, the control line 324 and the TFT T, the voltage level of the pixel electrode 220 is able to be the same as the image data V_{DATA}, thus avoiding the image quality from deterioration. Thus, it is not necessary to have the data refreshing frame by frame through the scan line SL and the data line DL in the present invention.

To explain the present invention, several kinds of memory cells in the embodiments are given hereinafter. Since the memory cells of the present invention are made by integrating an oxide-nitride-oxide structure (ONO structure) into a low temperature polysilicon TFT (LTPS-TFT), the manufacturing process of these memory cells provided by the present invention can be accordingly integrated with the currently used manufacturing process of LTPS-TFTs. In other words, if the voltage applied to the control gate is not sufficient for “programming” or “erasing”, the memory cell structure described hereinafter can still be used as a TFT.

### The First Embodiment

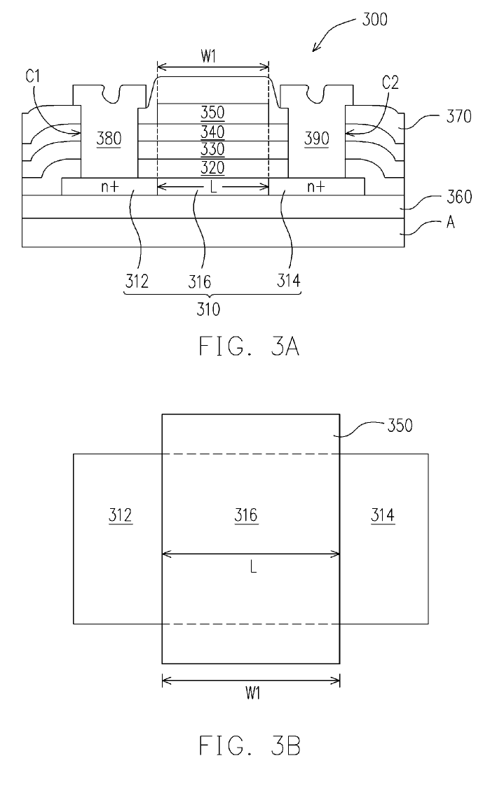

FIG. 3A and FIG. 3B are diagrams of a memory cell in the first embodiment of the present invention. Referring to FIG. 3A, a memory cell 300 of the present embodiment is suitable for being disposed on a substrate A, and the substrate A is, for example, a glass substrate or other transparent substrate. The memory cell 300 comprises a poly-Si island 310, a first dielectric layer 320, a trapping layer 330, a second dielectric layer 340 and a control gate 350. The poly-Si island 310 is disposed on the substrate A and includes a source doped region 312, a drain doped region 314 and a channel region 316 disposed between the source doped region 312 and the drain doped region 314. The first dielectric layer 320 is disposed on the poly-Si island 310, and the trapping layer 330 is disposed on the first dielectric layer 320. The second dielectric layer 340 is disposed on the trapping layer 330 and the control gate 350 is disposed on the second dielectric layer 340. In the following paragraphs, elements in the memory cell 300 will be described in details.

In the present embodiment, the source doped region 312 and the drain doped region 314 of the poly-Si island 310 is a N-type doped region with a higher dopant concentration (N+), while the channel region 316 in the poly-Si island 310 is a intrinsic or N-type poly-Si. N-type channel doping regions with a lower dopant concentration (N−).

In the present embodiment, the first dielectric layer 320 can be considered as a charge tunneling layer, the material of the first dielectric layer 320 is, for example, silicon dioxide or other dielectric materials able to be tunneled by charges, and the thickness of the first dielectric layer 320 is, for example, about 150 Angstroms. The trapping layer 330 can be considered as a charge storage layer, the material of the trapping layer 330 is, for example, silicon nitride or other thin films capable of trapping charges, and the thickness of the trapping layer 330 is, for example, about 250 Angstroms. In addition, the second dielectric layer 340 can be considered as a charge blocking layer, the material of the second dielectric layer 340 is, for example, silicon dioxide or other dielectric materials able to prevent injecting charges, and the thickness of the second dielectric layer 340 is, for example, about 300 Angstroms.

As shown in FIG. 3A, to prevent the impurities in the substrate A from diffusing into the poly-Si island310, the memory cell 300 of the embodiment can further include a buffer layer 360 disposed between the substrate A and the poly-Si island 310. To effectively block the impurities from the substrate A, the buffer layer 360 can be a silicon nitride thin film or other thin films capable of blocking the impurities.

Referring to FIG. 3A, to enhance the reliability of the memory cell 300, the memory cell 300 of the embodiment can further include a protection layer 370 for covering the poly-Si island 310, the first dielectric layer 320, the trapping layer 330, the second dielectric layer 340 and the control gate 350. The material of the above-mentioned protection layer 370 is, for example, silicon oxide, silicon or a combination thereof.

For applying a voltage to the source doped region 312 and the drain doped region 314, the memory cell 300 of the embodiment can further include a source contact metal 380 and a drain contact metal 390. The source contact metal 380 is electrically connected to the source doped region 312, while the drain contact metal 390 is electrically connected to the drain doped region 314. Moreover, the first dielectric layer 320, the trapping layer 330, the second dielectric layer 340 and the protection layer 370 have a contact C1 and a contact C2. Hence, the source contact metal 380 can be electrically connected to the source doped region 312 through the contact C1, while the drain contact metal 390 can be electrically connected to the drain doped region 314 through the contact C2.

It is clear from FIGS. 3A and 3B that in the memory cell 300 of the embodiment, the control gate 350 is disposed over the channel region 316 without overlapping with the source doped region 312 and the drain doped region 314. In other words, the width W1 of the control gate 350 is equal to the length L of the channel region 316.

Note that the above-described poly-Si island 310, the first dielectric layer 320, the trapping layer 330, the second dielectric layer 340 and the control gate 350 have formed a workable memory cell already. Anyone skilled in the art is able to make an appropriate addition/deletion or modification to the structure to meet the requirement of their own after referring the contents of the present invention without departing from the scope or spirit of the invention.

During a programming operation of the memory cell 300operation, a high voltage (for example, 20 volt) is applied to the control gate 350 . The control gate 350 with a high voltage is able to draw the electrons from the channel region 316, tunneling through the first dielectric layer 320 and then being trapped in the trapping layer 330. On the other hand, during an erasing operation of the memory cell 300operation, a high voltage (for example, −40 volt) is applied to the control gate 350. The control gate 350 with a high voltage at the time is able to push the electrons from the trapping layer 330 by means of a repulsive force or to draw the holes from the channel region 316, enabling the holes to tunnel through the first dielectric layer 320 and to recombine the electrons trapped in the trapping layer 330.

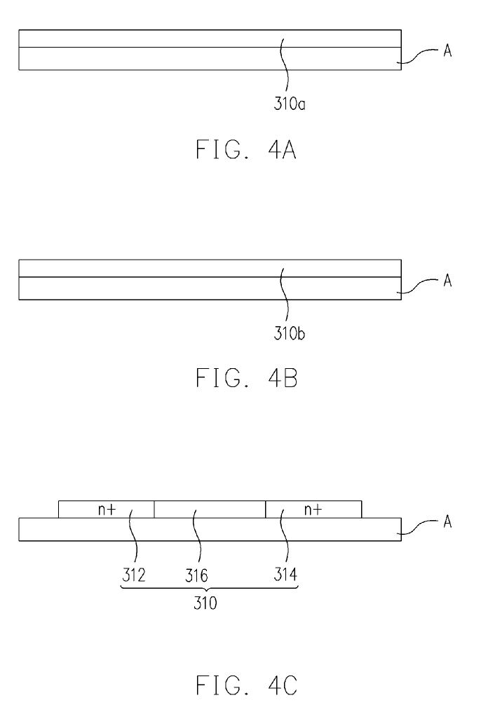

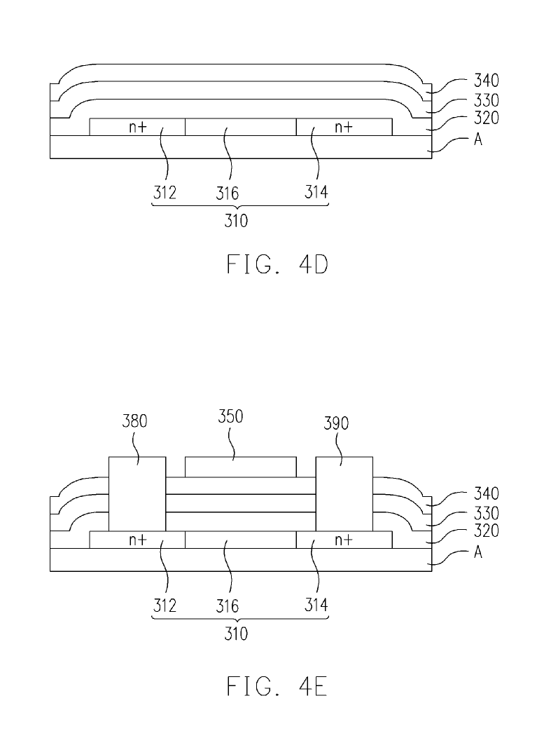

FIGS. 4A˜4E are diagrams showing the steps of the manufacturing process of the memory cell in FIG. 3A. Referring to FIG. 4A, a substrate A is provided and an amorphous silicon layer 310a is formed on the substrate A. In the present embodiment, the amorphous silicon layer 310a is formed by conducting, for example, a chemical vapor deposition (CVD) process. Note that prior to forming the amorphous silicon layer 310a in the embodiment, a buffer layer (not shown) can be optionally formed for blocking the impurities from the substrate A.

Referring to FIG. 4B, after forming the amorphous silicon layer 310a, an annealing process is conducted to fuse the amorphous silicon layer 310a on the substrate A, so that the amorphous silicon layer 310a is recrystallized and becomes a polysilicon layer 310b. In the embodiment, the annealing process is, for example, an excimer laser annealing process (ELA process).

Referring to FIG. 4C, after forming the polysilicon layer 310b, a patterning process is performed to the polysilicon layer 310b, followed by performing a doping process to the patterned polysilicon layer 310b. Thus, the poly-Si island 310 having the source doped region 312, the drain doped region 314 and the channel region 316 is formed.

Referring to FIG. 4D, after forming the poly-Si island 310, the first dielectric layer 320, the trapping layer 330 and the second dielectric layer 340 are sequentially formed on the poly-island 310. In the embodiment, the first dielectric layer 320, the trapping layer 330 and the second dielectric layer 340 are formed by, for example, chemical vapor deposition (CVD).

Referring to FIG. 4E, after forming the second dielectric layer 340, a control gate 350 is formed on the second dielectric layer 340. Then, the first dielectric layer 320, the trapping layer 330 and the second dielectric layer 340 are patterned to partially expose the source doped region 312 and the drain doped region 314. The source contact metal 380 and the drain contact metal 390 are respectively formed on the exposed source doped region 312 and exposed drain doped region 314.

Remarkably, prior to patterning the first dielectric layer 320, the trapping layer 330 and the second dielectric layer 340, a protection layer (not shown) can be formed in advance for covering the control gate 350.

### The Second Embodiment

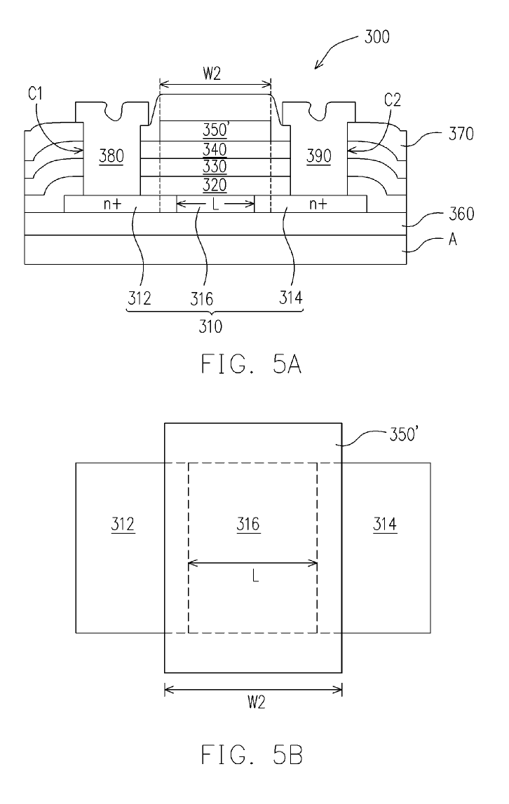

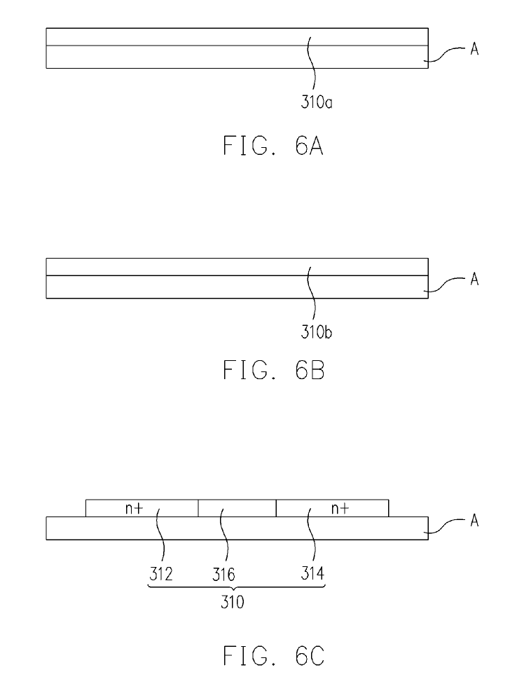

FIG. 5A and FIG. 5B are diagrams of a memory cell in the second embodiment of the present invention. Referring both FIG. 5A and FIG. 5B, the memory cell 300′ of the embodiment is similar to the first embodiment except the control gate 350′ of the memory cell 300′ is disposed over a portion of the source doped region 312, a portion of the drain doped region 314 and the channel region 316. In other words, the width W2 of the control gate 350′ is larger than the length L of the channel region 316 in this embodiment.

In the memory cell 300′ of the embodiment, since the control gate 350′ partially overlaps the source doped region 312 and the drain doped region 314 and the dopant concentration in the source and drain doped regions 312 and 314 is higher than that of the channel region 316, the memory cell 300′ of this embodiment has a better programming/erasing capacity than the first embodiment.

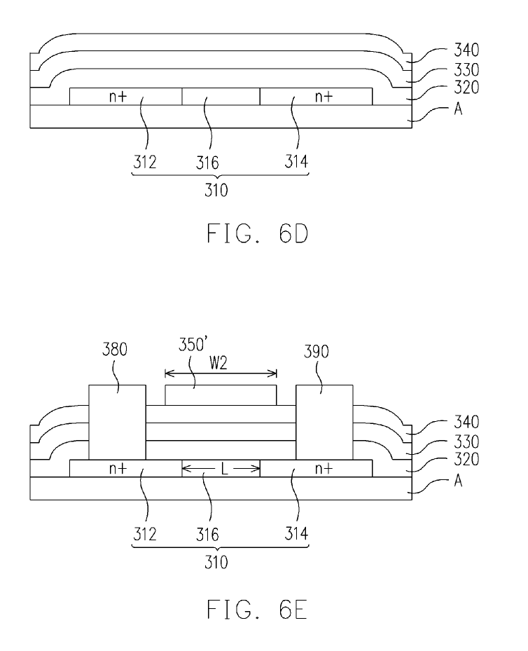

FIGS. 6A˜6E are diagrams showing the steps of the manufacturing process of the memory cell in FIG. 5A. Referring to FIGS. 6A˜6E, the manufacturing process of the memory cell 300′ in the embodiment is similar to the first embodiment except the width W2 of the fabricated control gate 350′ (see FIG. 6E) is larger than the length L of the channel region 316 in this embodiment.

### The Third Embodiment

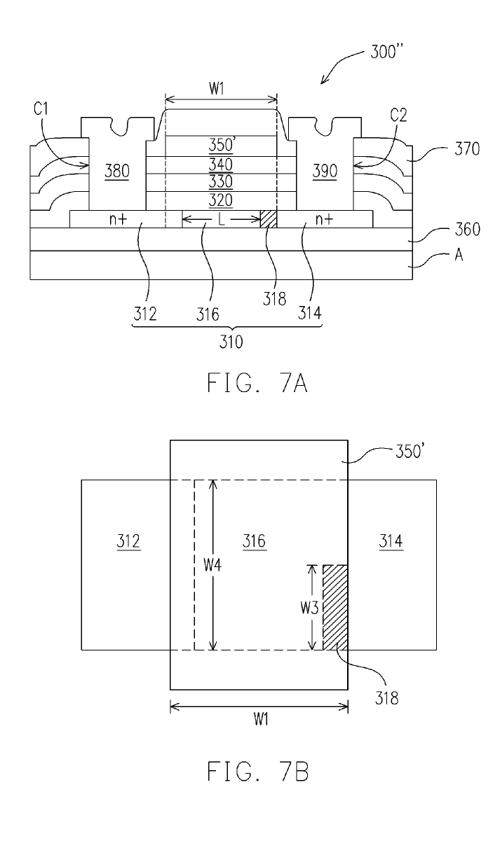

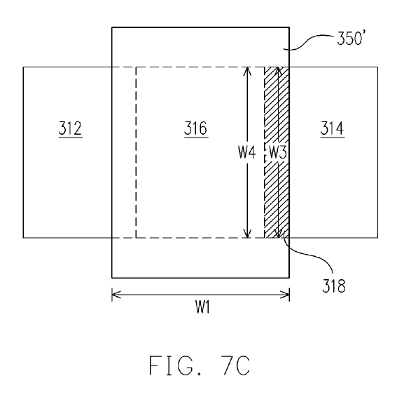

FIGS. 7A, 7B and 7C are diagrams of a memory cell in the third embodiment of the present invention. Referring to FIGS. 7A, 7B and 7C, the memory cell 300″ in the embodiment is similar to the first embodiment except the poly-island 310 in the embodiment further comprises a charge-induced doped region 318 disposed between the channel region 316 and the drain doped region 314 and below the control gate 350′.

It can be seen from FIGS. 7B and 7C that the width W3 of the charge-induced doped region 318 is smaller than the width W4 of the channel region 316 (shown in FIG. 7B), or is equal to the width W4 of the channel region 316 (shown in FIG. 7C) and the charge-induced doped region 318 is, for example, a P-type doped region. Note that since the charge-induced doped region 318 is a P-type doped region and the drain doped region 314 is a N-type doped region, the P-N junction between the charge-induced doped region 318 and the drain doped region 314 makes the memory cell 300″ in this embodiment have a better programming/erasing capability.

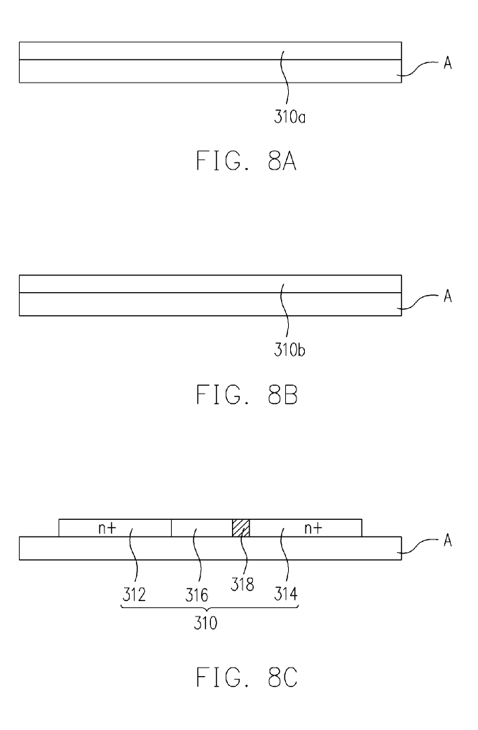

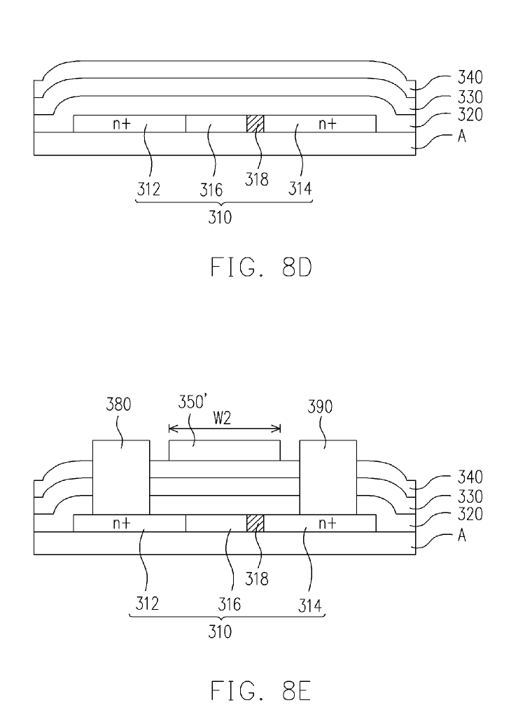

FIGS. 8A˜8E are diagrams showing the steps of the manufacturing process of the memory cell in FIG. 7A. Referring to FIGS. 8A˜8E the manufacturing process of the memory cell 300″ in the embodiment is similar to the second embodiment except a charge-induced doped region 318 is fabricated between the channel region 316 and the drain doped region 314 (shown in FIG. 8E).

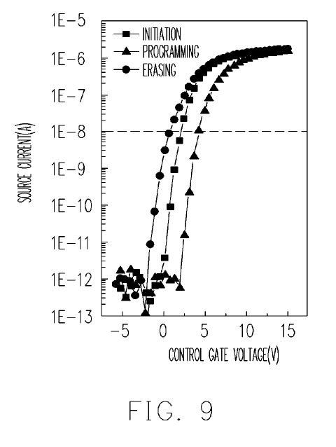

FIGS. 9˜12 are graphic charts showing characteristic curves of the memory cells in the present invention. Referring to FIG. 9, it is a graphic chart of drain current ID VS. control gate voltage VG for the memory cells of the present invention. In the FIG. 9, a voltage of 20 volt is applied to the control gate for conducting a programming operation, while a voltage of −40 volt is applied to the control gate for conducting an erasing operation. It is clear from FIG. 9 that during the programming or the erasing operation, the sub-threshold swing remains unchanged, which suggests the threshold voltage shift of the memory cell is caused by electrons trapped in the trapping layer, not by deterioration of the memory cell.

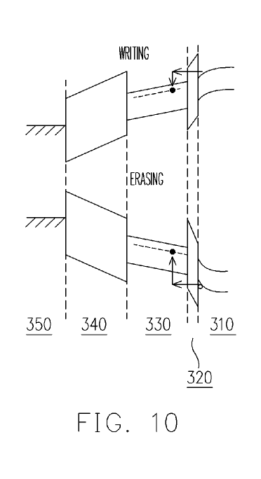

FIG. 10 is a diagram of energy-bands corresponding to programming and erasing the memory cells of the present invention, respectively. Referring to FIG. 10, when the memory cell conducts a programming operation, the electrons from the poly-island 310 would tunnel through the first dielectric layer 320 and be trapped in the trapping layer 330. When the memory cell conducts an erasing operation, the electrons trapped in the trapping layer 330 would be repulsed or the holes in the channel region 316 would tunnel through the first dielectric layer 320 to recombine with the electrons trapped in the trapping layer 330. The second dielectric layer 340 can effectively prevent the charges of the control gate 350 from injecting the trapping layer 330.

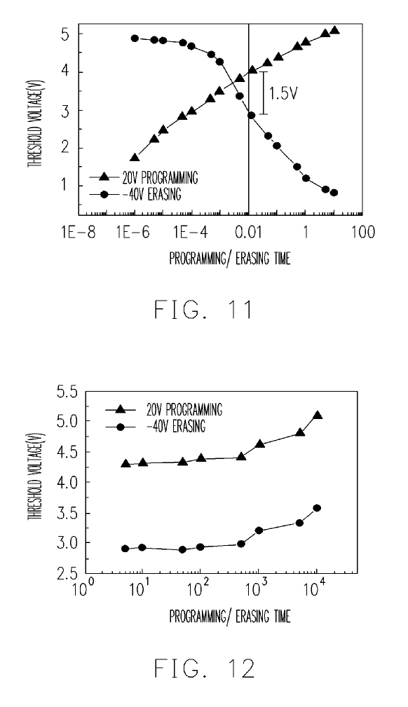

FIG. 11 is a graphic chart of the threshold voltage vs. programming/erasing time of the memory cells of the present invention. Referring to FIG. 11, when the control gate in the present invention is applied with a voltage of 20 volt and a voltage of −40 volt for a programming operation and an erasing operation, respectively, with a voltage applying duration of 0.01 second, the threshold voltage window is around 1.5 volt, which is enough to define a “0” state and a “1” state of a logic memory circuit.

FIG. 12 is a graphic chart of threshold voltage vs. programming/erasing times of the memory cells of the present invention. Referring to FIG. 12, when the control gate in the present invention is applied with a voltage of 20 volt and a voltage of −40 volt for a programming operation and an erasing operation, respectively, with a voltage applying duration of 0.01 second, the threshold voltage window is still able to remain at around 1.5 volt, even after the programming/erasing” operation being repeated for 10,000 times.

In summary, the present invention has at least the following advantages:

1. The process provided by the present invention can be integrated with the manufacturing process of the low temperature polysilicon TFT (LTPS-TFT) to fabricate the pixel structure having an embedded memory cell.

2. The memory cell of the present invention can be applicable to a transmissive LTPS-TFT LCD panel, a reflective LTPS-TFT LCD panel and a semi-transmissive and semi-reflective LTPS-TFT LCD panel, without the prior problem of reduced aperture ratios.

3. The present invention can enormously reduce the required TFT number required in the pixel structure and further improve the aperture ratio of the panel.

4. The pixel structure of the present invention is suitable for displaying static images and has a low power-consumption during displaying the static images.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A memory cell, suitable for being disposed on a substrate, comprising:
a poly-Si island, disposed on the substrate, wherein the poly-Si island comprises a source doped region, a drain doped region and a channel region residing between the source doped region and the drain doped region;
a first dielectric layer, disposed on the poly-Si island;
a trapping layer, disposed on the first dielectric layer;
a second dielectric layer, disposed on the trapping layer; and
a control gate, disposed on the second dielectric layer.

2. The memory cell as recited in claim 1, wherein the source doped region and the drain doped region are N-type doped regions.

3. The memory cell as recited in claim 1, wherein a material of the first dielectric layer is silicon dioxide, a material of the trapping layer is silicon nitride and a material of the second dielectric layer is silicon dioxide.

4. The memory cell as recited in claim 1, wherein the control gate is disposed over the channel region.

5. The memory cell as recited in claim 1, wherein the control gate is disposed over the channel region, a portion of the source doped region and a portion of the drain doped region.

6. The memory cell as recited in claim 1, wherein the poly-Si island further comprises a charge-induced doped region between the channel region and the drain doped region, and wherein the charge-induced doped region is disposed below the control gate.

7. The memory cell as recited in claim 6, wherein a width of the charge-induced doped region is smaller than or equal to a width of the channel region.

8. The memory cell as recited in claim 6, wherein the charge-induced doped region is P-type doped region.

9. The memory cell as recited in claim 1, further comprising a buffer layer disposed between the substrate and the poly-Si island.

10. The memory cell as recited in claim 1, further comprising:
a source contact metal, electrically connected to the source doped region; and
a drain contact metal, electrically connected to the drain doped region.

11. A pixel structure, suitable for electrically connecting a scan line and a data line; the pixel structure comprising:
an active device;
a pixel electrode, electrically connected to the scan line and the data line through the active device;
a control circuit;
a memory cell, electrically connected with the control circuit and the pixel electrode, wherein the memory cell comprises:
a poly-Si island, disposed on the substrate, wherein the poly-Si island comprises a source doped region, a drain doped region and a channel region between the source doped region and the drain doped region;
a first dielectric layer, disposed on the poly-Si island;
a trapping layer, disposed on the first dielectric layer;
a second dielectric layer, disposed on the trapping layer; and
a control gate, disposed on the second dielectric layer.

12. The pixel structure as recited in claim 11, wherein the active device comprises a thin film transistor (TFT).

13. The pixel structure as recited in claim 11, wherein the control circuit comprises a thin film transistor (TFT).

14. The pixel structure as recited in claim 11, wherein the source doped region and the drain doped region are N-type doped regions.

15. The pixel structure as recited in claim 11, wherein a material of the first dielectric layer is silicon dioxide, a material of the trapping layer is silicon nitride and a material of the second dielectric layer is silicon dioxide.

16. The pixel structure as recited in claim 11, wherein the control gate is disposed over the channel region.

17. The pixel structure as recited in claim 11, wherein the control gate is disposed over the channel region, a portion of the source doped region and a portion of the drain doped region.

18. The pixel structure as recited in claim 11, wherein the poly-island further comprises a charge-induced doped region between the channel region and the drain doped region, and wherein the charge-induced doped region is disposed below the control gate.

19. The pixel structure as recited in claim 18, wherein a width of the charge-induced doped region is smaller than or equal to a width of the channel region.

20. The pixel structure as recited in claim 18, wherein the charge-induced doped region is a P-type doped region.

21. The pixel structure as recited in claim 11, further comprising a buffer layer disposed between the substrate and the poly-island.

22. The pixel structure as recited in claim 11, further comprising:
a source contact metal, electrically connected to the source doped region; and
a drain contact metal, electrically connected to the drain doped region.

23. A manufacturing process of memory cells, comprising:
forming a poly-island on a substrate, wherein the poly-island comprises a source doped region, a drain doped region and a channel region residing between the source doped region and the drain doped region;
sequentially forming a first dielectric layer, a trapping layer and a second dielectric layer on the poly-island; and
forming a control gate on the second dielectric layer.

24. The manufacturing process as recited in claim 23, wherein the method for forming the poly-island comprises:
forming an amorphous silicon layer;
re-crystallizing the amorphous silicon layer by an annealing process to convert the amorphous silicon layer into a polysilicon layer;
patterning the polysilicon layer; and
doping the polysilicon layer for forming the source doped region, the drain doped region and the channel region.

25. The manufacturing process as recited in claim 24, wherein the annealing process comprises an excimer laser annealing process (ELA process).

26. The manufacturing process as recited in claim 24, wherein the method for forming the source doped region and the drain doped region comprises doping N-type dopants to the polysilicon layer.

27. The manufacturing process as recited in claim 24, further comprising forming a charge-induced doped region between the channel region and the drain doped region, wherein the charge-induced doped region is disposed below the control gate.

28. The manufacturing process as recited in claim 27, wherein the method for forming the charge-induced doped region comprises doping P-type dopants to the polysilicon layer.

29. The manufacturing process as recited in claim 23, further comprising forming a buffer layer between the substrate and the poly-island.

30. The manufacturing process as recited in claim 23, further comprising: forming a source contact metal and a drain contact metal, wherein the source contact metal is electrically connected to the source doped region, while the drain contact metal is electrically connected to the drain doped region.
